(19) United States
(12) Patent Application Publication
(10) Pub. No.: US 2006/0125084 A1
(43) Pub. Date: Jun. 15, 2006

(54) Integration of micro-electro mechanical systems and active circuitry

(76) Inventors: Ronald S. Fazzio, Loveland, CO (US); Thomas E. Dungan, Fort Collins, CO (US)

Correspondence Address: AGILENT TECHNOLOGIES, INC.;INTELLECTUAL PROPERTY ADMINISTRATION, LEGAL DEPT., P.O. BOX 7599, M/S DL429, LOVELAND, CO, 80537-0599, US

(21) Appl. No.: 11/012,574

(22) Filed: Dec. 15, 2004

(51) Int. Cl. H01L 21/50; H01L 23/12

(52) U.S. Cl. 257/704; 438/125; 257/E23.193

(57) ABSTRACT

A single integrated wafer package includes a micro-electro mechanical system (MEMS) wafer, an active device wafer, and a seal ring. The MEMS wafer has a first surface and includes at least one MEMS component on its first surface. The active device wafer has a first surface and includes an active device circuit on its first surface. The seal ring is adjacent the first surface of the MEMS wafer such that a seal is formed about the MEMS component. An external contact is provided on the wafer package. The external contact is accessible externally to the wafer package and is electrically coupled to the MEMS device or active device circuit of the active device wafer.

### CROSS-REFERENCE TO RELATED APPLICATIONS

This Utility Patent Application is related to commonly assigned Utility Patent Application Serial No. XX/XXX,XXX, attorney docket no. 10040862-1, filed on the same date as the present application, and entitled WAFER BONDING OF MICRO-ELECTRO MECHANICAL SYSTEMS TO ACTIVE CIRCUITRY, which is herein incorporated by reference.

### BACKGROUND

This invention relates to fabrication of electrical devices at a wafer level. Specifically, a micro-electro mechanical system component is bonded to an active semiconductor component at the wafer level.

Many electrical devices are very sensitive and need to be protected from harsh external conditions and damaging contaminants in the environment. For micro-electro mechanical systems (MEMS) devices, such as film bulk acoustic resonators (FBAR), surface mounted acoustic resonators (SMR), and surface acoustic wave (SAW) devices, this is particularly true. Such MEMS devices have traditional been insulated in hermetic packages or by providing a microcap layer over the MEMS device to hermetically seal the device from the surrounding environment.

Such hermetically sealed MEMS devices must also provide access points so that electrical connections can be made to the MEMS device. For example, an FBAR device configured with a microcap in a wafer package must be provided with holes or vias, through the microcap or elsewhere so that electrical contact can be made with the FBAR device within the wafer package to the other external electrical components, such as semiconductor components. Because both MEMS devices and active semiconductor devices requires specialized fabrication sequences, directly constructing both MEMS devices and active circuitry on a single wafer requires significant comprises in performance, manufacturability, and cost.

For these and other reasons, a need exists for the present invention.

### SUMMARY

One aspect of the present invention provides a single integrated wafer package including a micro-electro mechanical system (MEMS) wafer, an active device wafer, and a seal ring. The MEMS wafer has a first surface and includes at least one MEMS component on its first surface. The active device wafer has a first surface and includes an active device circuit on its first surface. The seal ring is adjacent the first surface of the MEMS wafer such that a hermetic seal is formed about the MEMS component. An external contact is provided on the wafer package. The external contact is accessible externally to the wafer package and is electrically coupled to the active device circuit of the active device wafer.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates a cross-sectional view of a single integrated wafer package including a MEMS wafer and an active device wafer in accordance with the present invention.

FIGS. 2-4 illustrate process steps for fabricating the single integrated wafer package of FIG. 1 in accordance with the present invention.

FIG. 5 illustrates a cross-sectional view of an alternative single integrated wafer package including a MEMS wafer and an active device wafer in accordance with the present invention.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following Detailed Description, therefore, is not to be taken in a limiting sense, and the scope of the present invention is defined by the appended claims.

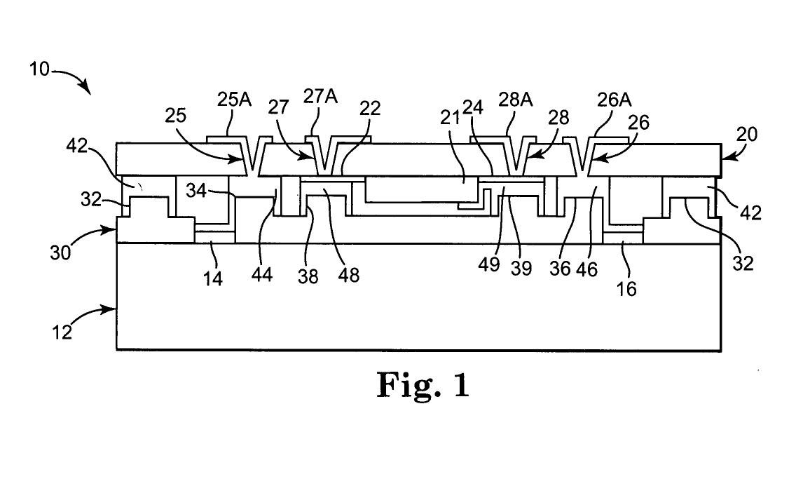

FIG. 1 illustrates single integrated wafer-level package 10 in accordance with the present invention. Wafer package 10 includes active device wafer 12 and MEMS wafer 20. In one embodiment, MEMS wafer 20 is a film bulk acoustic resonator (FBAR) substrate wafer and active device wafer 12 is a complementary metal oxide semiconductor (CMOS) substrate wafer. Wafer package 10 combines MEMS wafer 20 and active device wafer 12 while each are still at the wafer level into a single integrated wafer package. Wafer package 10 then includes external contacts (25A, 26A, 27A, and 28A discussed further below), which are accessible externally to wafer package 10, such that it may be electrically coupled to other external components. Multiple wafer packages 10 (also referred to as “die” or “dice”) may be formed in accordance with the present invention.

In one embodiment, active device wafer 12 includes first and second interconnects 14 and 16, which are electrically coupled to active device circuitry such a CMOS circuit. Dielectric layer 30 is deposited adjacent active device wafer 12. Dielectric layer 30 is etched to form a plurality of raised portions or ridges. Specifically, ring ridge 32 is located at the periphery of active device wafer 12, and extends around the entire periphery. Also included are first and second outer ridges 34 and 36, as well as first and second inner ridges 38 and 39. In one embodiment, inner and outer ridges 34 and 36 and 38 and 39 do not encircle the die.

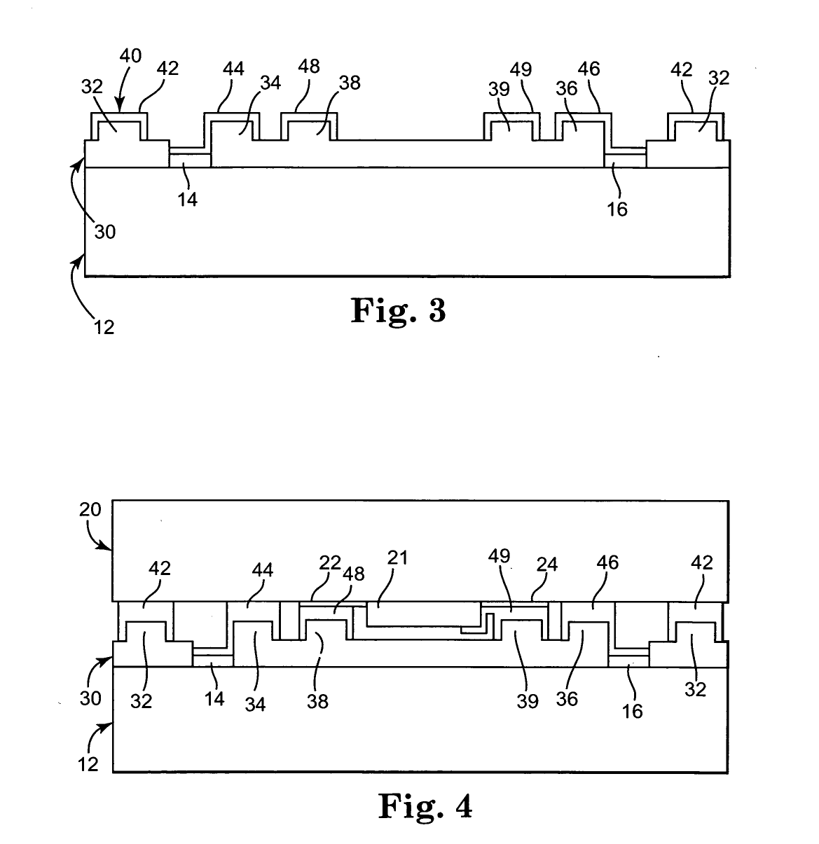

A metallization layer 40 (illustrated in FIG. 3) is deposited over dielectric layer 30 and etched, such that contacts are formed at certain locations relative to dielectric layer 30. Metallization layer 40 may also be deposited and patterned by a lift-off technique. The contacts formed by metallization layer 40 include ring contact 42, which is formed at the periphery of active device wafer 12 adjacent ring ridge 32, and extends around the entire periphery. Also formed are first and second outer contacts 44 and 46 (adjacent first and second ridges 34 and 36), as well as first and second inner contacts 48 and 49 (adjacent first and second inner ridges 38 and 39).

Finally, in wafer package 10, MEMS wafer 20 is placed over the combination of active device wafer 12, dielectric layer 30, and metallization layer 40. In one embodiment of wafer package 10, MEMS wafer 20 is bonded with a thermocompression bond over the combination of active device wafer 12, dielectric layer 30, and metallization layer 40.

MEMS wafer 20 includes MEMS components such an FBAR 21. A single MEMS component, multiple components, or alternative MEMS components, such as SMR, may also or alternatively be provided on MEMS wafer 20. First and second MEMS-wafer contacts 22 and 24 are also formed on MEMS wafer 20, and each are electrically coupled to FBAR 21. MEMS wafer 20 also includes first and second outer vias 25 and 26, as well as first and second inner vias 27 and 28. Vias 25 through 28 provide access to inner wafer package 10 from outside the device. First and second outer MEMS-wafer contacts 25A and 26A are provided within first and second outer vias 25 and 26 and first and second inner MEMS-wafer contacts 27A and 28A are provided within first and second inner vias 27 and 28. MEMS-wafer contacts 25A through 28A provide electrical contact from outside wafer package 10 to its inside. In one embodiment, MEMS wafer 20 may be provided with a peripheral bond pad similar to, and aligned with, ring contact 42 in order to help form a good seal of MEMS wafer 20 to active device 12.

In one embodiment, electrical contact external to wafer package 10 is provided to active device circuitry on active device wafer 12. Specifically, first and second outer MEMS-wafer contacts 25A and 26A are coupled to first and second outer contacts 44 and 46, which are in turn coupled to first and second interconnects 14 and 16. First and second interconnects 14 and 16 are coupled to the active device circuitry on active device wafer 12. In this way, first and second outer MEMS-wafer contacts 25A and 26A are provided on wafer package 10 to provide electrical connection of active device wafer 12 to external devices. First and second interconnects 14 and 16 are meant to be illustrative and are in no way meant to be limiting. For example, two interconnects may be useful in some applications, but one skilled in the art will recognize that multiple additional interconnects may be employed consistent with the present invention.

In one embodiment, electrical contact external to wafer package 10 is also provided to MEMS components on MEMS wafer 20, such as FBAR 21. Specifically, first and second inner MEMS-wafer contacts 27A and 28A are coupled to first and second MEMS contacts 22 and 24, which are in turn coupled to FBAR 21. In this way, first and second inner MEMS-wafer contacts 27A and 28A are provided on wafer package 10 to provide electrical connection of MEMS component FBAR 21 to external devices.

In an alternative embodiment, electrical contact can be provided directly between MEMS wafer 20 and active device wafer 12 at the wafer level. For example, dielectric layer 30 can be further etched so that first and second inner contacts 48 and 49 extend down to the active de vice circuit on active device wafer 12 thereby coupling first and second MEMS-wafer contacts 22 and 24 to the active device circuitry. In such an embodiment, first and second inner vias 27 and 28 may be done away with such that the only electrical connection to MEMS wafer 20 is via the direct internal connection to the active device circuitry. In other alternative embodiments, external electrical contact may be provided by a via, or a plurality of vias, through active device wafer 12.

In wafer package 10, ring ridge 32 protects MEMS wafer 20, while at the same time, external electrical connection is provided to active device wafer 12, and/or MEMS wafer 20. In accordance with the present invention, wafer package 10 is fabricated at a wafer level such that active device wafer 12 and MEMS wafer 20 are already electrically coupled when wafer package 10 is singulated. In this way, the steps of electrically coupling MEMS wafer 20 to an active device wafer 12 after singulation is thereby avoided.

Dielectric layer 30 essentially provides protection and a seal to MEMS component FBAR 21. Specifically, ring ridge 32 of dielectric layer 30 extends between MEMS wafer 20 and active device wafer 12 around their periphery immediately adjacent ring contact 42. In this way, ring ridge 32 surrounds FBAR 21 (as well as various electrical through contacts). Thus, the combination of ring ridge 32, ring contact 42, active device wafer 12, and MEMS wafer 20 forms a sealed chamber. In one embodiment, this sealed chamber is hermetically sealed. This chamber seals MEMS component FBAR 21.

In addition, sealing is also provided by the other ridge features to seal around the vias. Specifically, first and second outer ridges 34 and 36 provide a seal around first and second outer vias 25 and 26, respectively. Also, first and second inner ridges 38 and 39 provide a seal around first and second inner vias 27 and 28, respectively.

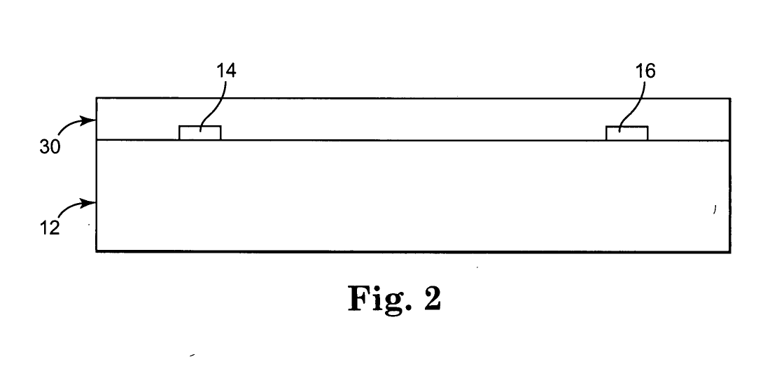

Fabrication of wafer package 10 according to one fabrication sequence is illustrated in FIGS. 2-4. In FIG. 2, active device wafer 12 is illustrated with first and second interconnects 14 and 16 on its surface. First and second interconnects 14 and 16 are electrically coupled to active device circuitry on active device wafer, such a CMOS circuit. Dielectric layer 30 is also illustrated deposited adjacent active device wafer 12. In an alternative embodiment, dielectric layer 30 may be deposited on MEMS wafer 20, and etched to forms a seal. In some other applications, application of dielectric layer 30 on MEMS wafer 20 may be impractical.

In one embodiment, the dielectric layer must be thick enough to allow etching of portions of dielectric layer 30 to create a sealed chamber for sealing MEMS components after attachment to a MEMS wafer. Also in one embodiment, dielectric layer 30 must be capable of withstanding bonding conditions, which may expose it to temperatures in a 300° C. to 425° C. range at 10 MPa to 60 MPa local pressure. In some cases, it must withstand these conditions for up to two hours. Dielectric layer 30 may be silicon nitride, silicon oxide and other similar materials.

In some alternative embodiments, some additional layers of silicon may be sputtered over dielectric layer 30 in order to aid in forming the sealing chamber such that is hermetically sealed and provides a vapor barrier. It is desirable in some applications to keep vapor out of the hermetic chamber in order to avoid the “popcorn effect” that can cause the hermetic chamber to “pop” open when heat acts upon vapor in the chamber. In some applications, degradation of the FBAR device performance may also occur with a hermeticity failure. However, in other MEMS devices consistent with the present invention, a hermetic seal may not be required such that these additional layers will not be needed.

FIG. 3 illustrates a later stage of the fabrication sequence where dielectric layer 30 has been etched to form a plurality of raised portions or ridges, thereby forming a gasket structure. This may be accomplished in one embodiment by patterning a mask on the combination of active device wafer 12 and dielectric layer 30, and then etching the final dimensions. Specifically, ring ridge 32 is formed at the periphery of active device wafer 12, and extends around the entire periphery. First and second outer ridges 34 and 36, as well as first and second inner ridges 38 and 39 are also formed in the etching process. In one embodiment, inner and outer ridges 34 and 36 and 38 and 39 do not extend around the periphery of the wafer, and are formed to be adjacent the vias of the MEMS wafer. Additional patterning of a mask and additional etching may be required between ring ridge 32 and first outer ridge 34 to assure that they are separated such that first interconnect 14 is exposed though dielectric layer 30. Similarly, additional etching may be required between ring ridge 32 and second outer ridge 36 to assure that they are separated such that second interconnect 16 is exposed though dielectric layer 30.

A metallization layer 40 is then deposited over dielectric layer 30. Metallization layer 40 may be deposited, masked, and etched, or it may be established with a lift-off or similar process. In this way, contacts are formed at certain locations relative to dielectric layer 30. Specifically, ring contact 42 is formed at the periphery of active device wafer 12 adjacent ring ridge 32, and extends around the entire periphery. Also formed are first and second outer contacts 44 and 46 (adjacent first and second ridges 34 and 36), as well as first and second inner contacts 48 and 49 (adjacent first and second inner ridges 38 and 39).

Metallization layer 40 may be gold or some other metallization, and it may provide metallization for the bond of active device wafer 12 to MEMS wafer 20 and also provide contact with first and second interconnects 14 and 16.

FIG. 4 illustrates a later stage of the fabrication sequence where active device wafer 12 is bonded to MEMS wafer 20. Wafer package 10 includes MEMS wafer 20 and active device wafer 12 with dielectric layer 30 and metallization layer 40 sandwiched between them. MEMS wafer 20 may be bonded to active device wafer 12 using a thermocompression or other bonding process.

In one embodiment, the fabrication sequence is then completed by backgrinding the wafer combination illustrated in FIG. 4. Specifically, a backside of MEMS wafer 20, that is, the side opposite that facing active device wafer 12, is ground down and then masked and etched to from backside vias 25 through 28 (illustrated in FIG. 1). Next, backside metallization is placed for interconnection to MEMS components (first and second inner MEMS-wafer contacts 27A and 28A placed for connection with first and second MEMS contacts 22 and 24) and for interconnection to the active device circuitry on active device layer 12 (first and second outer MEMS-wafer contacts 25A and 26A are placed for connection to first and second outer contacts 44 and 46 and to first and second interconnects 14 and 16). This backside metallization may be deposited and etched, pattern plated, or established with a lift-off process.

In alternative embodiments, certain through vias may be used exclusively for interconnect directly to active device base wafer 12, and others vias may be used to make contact with the MEMS wafer 20, and MEMS components thereon. In some applications, it may be preferable to have contact to the MEMS components established with the active device wafer 12 directly, without a backside via making contact to the MEMS components. In other instances, only interconnect to the MEMS components with the vias is desirable, with the active device wafer 12 making contact to the MEMS components without using a via. In other embodiments, active device wafer 12 may be background with vias and metallization added to form electrical contacts to the MEMS components and/or the active device circuitry through the active device wafer 12.

Finally, according to one embodiment of the invention, die are singulated and used in either a bump bonded or wire bonded application. In wafer package 10, the combination of MEMS wafer 20, active wafer 12 and ring ridge 30 provide a hermetic seal to protect MEMS component FBAR 21, and also provides electrical connection with both MEMS wafer 20 and active device wafer 12. In accordance with one embodiment of the present invention, wafer package 10 is fabricated at a wafer level such that MEMS wafer 20 and active device wafer 12 are already electrically coupled when wafer package 10 is singulated. In this way, the steps of electrically coupling MEMS wafer 20 to an active device wafer 12 after singulation is thereby avoided, and wafer package 10 is provided with external electrical contacts.

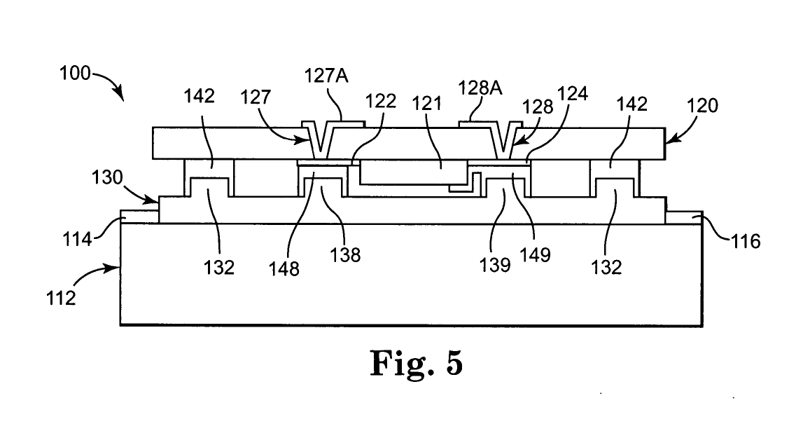

FIG. 5 illustrates a single integrated wafer-level package 100 in accordance with an alternative embodiment of the present invention. Wafer package 100 includes active device wafer 112 and MEMS wafer 120. In one embodiment, MEMS wafer 120 is a film bulk acoustic resonator (FBAR) substrate wafer and active device wafer 120 is a complementary metal oxide semiconductor (CMOS) substrate wafer. Wafer package 100 combines MEMS wafer 120 and active device wafer 112 while each are still at the wafer level into a single integrated wafer package. Wafer package 100 then includes external contacts (127A and 128A and interconnects 114 and 116 discussed further below), which are accessible externally to wafer package 100, such that it may be electrically coupled to other external components.

In one embodiment, active device wafer 112 includes first and second interconnects 114 and 116, which are electrically coupled to active device circuitry such a CMOS circuit. Dielectric layer 130 is deposited adjacent active device wafer 112. Dielectric layer 130 is etched to form a plurality of raised portions or ridges. Specifically, ring ridge 132 is located at the periphery of active device wafer 112, and extends around the entire periphery. Also included are first and second inner ridges 138 and 139.

A metallization layer is deposited over dielectric layer 130 and etched, such that contacts are formed at certain locations relative to dielectric layer 130. Specifically, ring contact 142 is formed at the periphery of active device wafer 120 adjacent ring ridge 132, and extends around the entire periphery. Also formed are first and second inner contacts 148 and 149 (adjacent first and second inner ridges 138 and 139).

Finally, in wafer package 100, MEMS wafer 120 is placed over the combination of active device wafer 112, dielectric layer 130, and the metallization layer. MEMS wafer 120 includes MEMS components such an FBAR 121. A single MEMS component, multiple components, or alternative MEMS components, such as a SMR, may also or alternatively be provided on MEMS wafer 120. First and second MEMS-wafer contacts 122 and 124 are also formed on MEMS wafer 120, and each are electrically coupled to FBAR 121. MEMS wafer 120 also includes first and second inner vias 127 and 128. Vias 127 and 128 provide access to inner wafer package 100 from outside the device. First and second inner MEMS-wafer contacts 127A and 128A are provided within first and second inner vias 127 and 128. MEMS-wafer contacts 127A and 128A provide electrical contact from outside wafer package 100 to its inside. In one embodiment, MEMS wafer 120 may be provided with a peripheral bond pad similar to, and aligned with, ring contact 142 in order to help form a good seal of MEMS wafer 120 to active device 112.

In one embodiment, wafer package 100 allows external interconnect to be made with active device wafer 112 on the side of the wafer, rather than internally through the wafer die as with the embodiment illustrated in FIGS. 1-4. In alternative embodiments, external interconnect to MEMS wafer 120 may also be routed to the side, or brought out the back of the wafer with vias 127A and 128A discussed further below.

With the embodiment illustrated in FIG. 5, interconnect to active device wafer 112 may be exposed with either a partial saw or with a mask followed by an etch process. With the partial saw cut, cuts through MEMS wafer 120 are offset with respect to cuts through active device wafer 112 so that a standoff distance is provided by the partial saw cuts. In other words, after the cuts are made MEMS wafer 120 is narrower than is active device wafer 112. In this way, the standoff distance between MEMS wafer 120 and active device wafer 112 exposes first and second interconnects 114 and 116, thereby making them accessible for connecting wafer package 100 with external electronic devices. Such “side connection” to first and second interconnects 114 and 116 could be made, for example, by wire bonding to interconnects 114 and 116. With a etch process, the ends of MEMS wafer 120 could be etched to expose first and second interconnects 114 and 116 simultaneously with etching the backside MEMS wafer 120 to make vias 127A and 128A.

In one embodiment, electrical contact external to wafer package 100 is also provided to MEMS components on MEMS wafer 120, such as FBAR 121. Specifically, first and second inner MEMS-wafer contacts 127A and 128A are coupled to first and second MEMS contacts 122 and 124, which are in turn coupled to FBAR 121. In this way, first and second inner MEMS-wafer contacts 127A and 128A are provided on wafer package 100 to provide electrical connection of MEMS component FBAR 121 to external devices.

In an alternative embodiment, electrical contact can be provided directly between MEMS wafer 120 and active device wafer 112 at the wafer level. For example, dielectric layer 130 can be further etched so that first and second inner contacts 148 and 149 extend down to the active device circuit on active device wafer 112 thereby coupling first and second MEMS-wafer contacts 122 and 124 to the active device circuitry. In such an embodiment, first and second inner vias 127 and 128 may be done away with such that the only electrical connection to MEMS wafer 120 is via the direct internal connection to the active device circuitry.

In another embodiment, the side interconnects may be placed on MEMS wafer 120 instead of, or in addition to, on active device wafer 112. In other words, interconnects may be provided on MEMS wafer 120, and then may be exposed with either a partial saw or with a mask followed by an etch process in the same way as previously described. With the partial saw cut, cuts through active device wafer 112 are offset with respect to cuts through MEMS wafer 120 so that a standoff distance is provided by the partial saw cuts, so that active device wafer 112 is narrower than is MEMS wafer 120. In this way, the standoff distance between MEMS wafer 120 and active device wafer 112 exposes the interconnects.

In wafer package 100, ring ridge 132 protects MEMS wafer 120, while at the same time, external electrical connection is provided to active device wafer 112, and/or MEMS wafer 120. In accordance with one embodiment of the present invention, wafer package 100 is fabricated at a wafer level such that active device wafer 112 and MEMS wafer 120 are already electrically coupled when wafer package 100 is singulated. In this way, the steps of electrically coupling MEMS wafer 120 to an active device wafer 112 after singulation is thereby avoided.

Dielectric layer 130 essentially provides protection and a hermetic seal to MEMS component FBAR 121. Specifically, ring ridge 132 of dielectric layer 130 extends between MEMS wafer 120 and active device wafer 112 around their periphery immediately adjacent ring contact 142. In this way, ring ridge 132 surrounds FBAR 121 (as well as electrical through contacts). Thus, the combination of ring ridge 132, ring contact 142, active device wafer 112, and MEMS wafer 120 form a hermetic chamber. This hermetic chamber hermetically seals MEMS component FBAR 121.

With the wafer package of the present invention no microcap wafer is required. This will save processing steps and simplify fabrication, as well as save costs of fabrication.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A single integrated wafer package comprising:
a micro-electro mechanical system (MEMS) wafer having at least one MEMS component;
an active device wafer having an active device circuit;
a seal ring sandwiched between the MEMS wafer and the active device wafer such that a sealed chamber is formed about the MEMS component; and
an external contact to the wafer package, wherein the external contact is accessible externally to the wafer package and is electrically coupled to the active device circuit of the active device wafer.

2. The wafer package of claim 1 wherein the sealed chamber is a hermetically sealed chamber.

3. The wafer package of claim 1 wherein the MEMS wafer and the active device wafer are bonded together with a thermocompression bond.

4. The wafer package of claim 1 wherein the MEMS component is one of a group comprising a thin film acoustic resonator (FBAR) and a solidly mounted acoustic resonator (SMR).

5. The wafer package of claim 1 further including a dielectric layer that is etched to form a raised ridge that is the seal ring that forms the seal about the MEMS component and that aids in coupling the wafers together such that they form a single integrated component.

6. The wafer package of claim 5 wherein the seal is a hermetic seal.

7. The wafer package of claim 5 wherein the dielectric layer between the MEMS wafer and the active device wafer that forms the seal ring is made from the group comprising silicon nitride and silicon oxide.

8. The wafer package of claim 5 wherein the MEMS wafer further includes a plurality of vias through which an electrical connection is made between the active device circuit and the external contact.

9. The wafer package of claim 5 wherein the MEMS wafer further includes a plurality of vias through which an electrical connection is made between the MEMS component and the external contact.

10. The wafer package of claim 5 wherein the active device wafer further includes a plurality of vias through which an electrical connection is made between the active device circuit and the external contact.

11. The wafer package of claim 5 wherein the active device wafer further includes a plurality of vias through which an electrical connection is made between the MEMS component and the external contact.

12. The wafer package of claim 5 wherein the MEMS wafer has partial saw cuts such that interconnects on the active device wafer are accessible as side interconnects.

13. The wafer package of claim 5 wherein the active device wafer has partial saw cuts such that interconnects on the MEMS wafer are accessible as side interconnects.

14. The wafer package of claim 5 wherein a metallization layer is formed over the dielectric layer to facilitate electrical connection between the active device circuit and the MEMS component.

15. A method for fabricating a wafer package comprising:
providing an active device wafer with an interconnect that is electrically coupled to an active device circuit;
depositing a dielectric layer over the active device wafer;
etching the dielectric layer to form a raised ridge that forms a ring around a perimeter of the active device wafer; and
bonding a micro-electro mechanical system (MEMS) wafer having at least one MEMS component to the active device wafer at the wafer level, wherein the raised ridge also forms a ring around the MEMS component once bonded, such that raised ridge, MEMS wafer and active device wafer seal the MEMS component.

16. The method of claim 15 further including depositing a metallization layer over the dielectric layer in order to aid in bonding the MEMS wafer to the active device wafer.

17. The method of claim 15, wherein the seal formed by the raised ridge between the MEMS wafer and active device wafer is a hermetic seal.

18. The method of claim 15 further including fabricating through vias in the MEMS wafer to provide electrical contact points to the wafer package that are accessible externally to the wafer package.

19. The method of claim 15 further including fabricating through vias in the active device wafer to provide electrical contact points to the wafer package that are accessible externally to the wafer package.

20. The method of claim 15 further including making partial saw cuts to the MEMS wafer to provide access to electrical contact points within the wafer package that are accessible externally to the wafer package.

21. The method of claim 15 further including making partial saw cuts to the active device wafer to provide access to electrical contact points within the wafer package that are accessible externally to the wafer package.

22. The method of claim 15, wherein bonding the MEMS wafer to the active device wafer includes bonding the wafers together with a thermocompression bond.

23. A single integrated wafer package comprising:
a micro-electro mechanical system (MEMS) wafer having at least one MEMS component;
an active device wafer having an active device circuit;
sealing means between the MEMS wafer and the active device wafer for forming a seal around the MEMS component; and
an external contact to the wafer package, wherein the external contact is accessible externally to the wafer package and is electrically coupled to one of the group comprising the active device circuit of the active device wafer and the MEMS component of the MEMS wafer.
